(19) United States
(12) Patent Application Publication
(10) Pub. No.: US 2007/0264584 A1
(43) Pub. Date: Nov. 15, 2007

(54) PATTERN ARRANGEMENT METHOD OF SEMICONDUCTOR DEVICE

(75) Inventors: In-Sung KIM, Gyeonggi-do (KR); Sung-Soo SUH, Gyeonggi-do (KR); Suk-Joo LEE, Gyeonggi-do (KR); Sung-Hwan BYUN, Incheon-gwangyeoksi (KR); Sang-Wook KIM, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (JP)

(21) Appl. No.: 11/674,594

(22) Filed: Feb. 13, 2007

(30) Foreign Application Priority Data
Feb. 13, 2006 (KR) 2006-13856

(51) Int. Cl. G03F 1/00

(52) U.S. Cl. 430/5

(57) ABSTRACT

A pattern arrangement method of a semiconductor device is provided. In the pattern arrangement method, patterns are classified according to effective pitches and critical dimensions, and pattern dispersion is predicted according to the effective pitches and the critical dimensions by using a statistical analysis of process parameters. Two-dimensional coordinates of the effective pitches and the critical dimensions are constructed, and a dispersion map is made by arranging the predicted pattern dispersion on the corresponding coordinates. By arranging design patterns within a tolerance region of the dispersion map, the patterns satisfying the dispersion tolerance according to the significance of the layer and the design requirements can be arranged.

### CROSS-REFERENCE TO RELATED APPLICATIONS

This U.S. non-provisional patent application claims priority under 35 U.S.C. §119 to Korean Patent Application No. 2006-13856, filed on Feb. 13, 2006, the contents of which are hereby incorporated by reference in their entirety.

### BACKGROUND

1. Technical Field

The invention disclosed herein relates to a circuit arrangement method of a semiconductor device, and more particularly, to a pattern arrangement method that can minimize pattern deformation caused by process parameters.

2. Description of the Related Art

In manufacturing a semiconductor device, a lithography process is used to transfer photomask patterns on a wafer. Therefore, the quality of the photomask is very important in the lithography process. As the critical dimensions of semiconductor devices shrink, in accordance with demand for higher density and smaller size semiconductor devices, parameters inherent in the lithography process cause the patterns actually formed on the wafer to differ from those of the photomask. In forming the photomask according to the design of the semiconductor device, many attempts are being made to improve the quality of the photomask by compensating for these various parameters to improve the patterns that are actually formed by the lithography process.

The patterns transferred on the wafer are influenced by many factors including exposure energy, focus, optical properties of the exposure equipment, formation of the photoresist, and the development process, causing the decrease of critical dimension (CD) uniformity, the increase of mean to target (MTT), and the generation of optical proximity effect between a cell region and a peripheral region.

Further, patterns arranged on a mask to meet the design requirements of a semiconductor device are not accurately transferred on a wafer according to their various pitches and CDs. To solve this problem, assist features are arranged between design patterns on an actual wafer, considering the pitches and CDs of the patterns. Sub-resolution assist features (SRAF) having CDs below the resolution of the exposure equipment are arranged between design patterns according to a predetermined design rule in order to compensate the optical proximity effect caused by the change in the pitches of the patterns.

FIG. 1 illustrates an arrangement of assist features according to the related art.

Referring to FIG. 1, the assist features 12 are arranged according to a design rule previously set in a design tool. As illustrated in FIG. 1, bar patterns 10 are arranged such that their intervals gradually increase, and the assist features 12 are arranged between the bar patterns 10. The assist features are arranged to compensate for the optical proximity effect, so that the pattern produced on the wafer will be as close as possible to the design pattern. At this point, the number, CD, and pitch of the arranged assist features 12 are determined by a predetermined design rule. According to a conventional design rule, the assist features 12 are added when the interval of the adjacent bar patterns 10 is greater than a predetermined interval within a range in which shapes of the patterns 10 are not distorted. In this way, the number, CD, and pitch of one-dimensional assist features are determined and applied to two-dimensionally arranged design patterns. Then, the assist features are arranged according to the CD and pitch of the design patterns, thereby compensating the optical proximity effect.

FIGS. 2A through 2C are graphs illustrating CD distributions of patterns which are transferred on a wafer and in which various process parameters are considered, when assist features are arranged according to the related art.

Specifically, FIGS. 2A through 2C are graphs illustrating A type, B type, and C type pattern arrangements of FIG. 1, respectively. In the case of the A type pattern arrangement, the bar patterns having the CD of 170 nm are repeatedly arranged at a pitch of 500 nm. In the case of the B type pattern arrangement, the bar patterns having the CD of 170 nm are repeatedly arranged at a pitch of 650 nm. In the case of the C type pattern arrangement, the bar patterns having the CD of 170 nm are repeatedly arranged at a pitch of 800 nm.

It can be seen from FIGS. 2A through 2C that when the assist features are arranged between the bar patterns having the CD or 170 nm according to the conventional design rule and then the CD of the patterns transferred on the wafer is simulated while the process parameters are selected randomly, the dispersion of the patterns transferred on the wafer is greatly varied depending on the pitch of the bar patterns. That is, when the arrangement of the assist features is determined considering only the CD and the pitch of the patterns according to the conventional design rule, the optical proximity effect can be compensated. However, the CD dispersion is high because various process parameters are not considered. The invention addresses these and other disadvantages of the conventional art.

### SUMMARY

The invention provides a pattern arrangement method in which manufacturing process parameters influencing the dispersion of patterns are considered. The invention also provides a pattern arrangement method that can overcome the disadvantages of a design rule dependent on only the pitch and CD of patterns.

### BRIEF DESCRIPTION OF THE FIGURES

The accompanying figures are included to provide a further understanding of the invention, and are incorporated in and constitute a part of this specification. The drawings illustrate exemplary embodiments of the invention and, together with the description, serve to explain principles of the invention. In the figures:

FIG. 1 illustrates an arrangement of assist features according to the related art;

FIGS. 2A through 2C are graphs illustrating CD distributions of patterns according to the related art;

FIG. 3 is a flowchart illustrating a pattern arrangement method according to an embodiment of the invention;

FIG. 4 is a table listing the dispersion (3σ) of the pattern CDs transferred on the wafer according to the effective pitches and the CDs;

FIG. 5 illustrates a dispersion map made according to the effective pitches and the CDs of the patterns by standardizing the dispersion in the predetermined regions;

FIG. 6 illustrates a dispersion map in which the coordinates of the samples corresponding to the effective pitches and CDs are located at coordinates A, coordinates B, and coordinates C; and

FIG. 7 illustrates an arrangement of assist features corresponding to pattern pitches according to an embodiment of the invention.

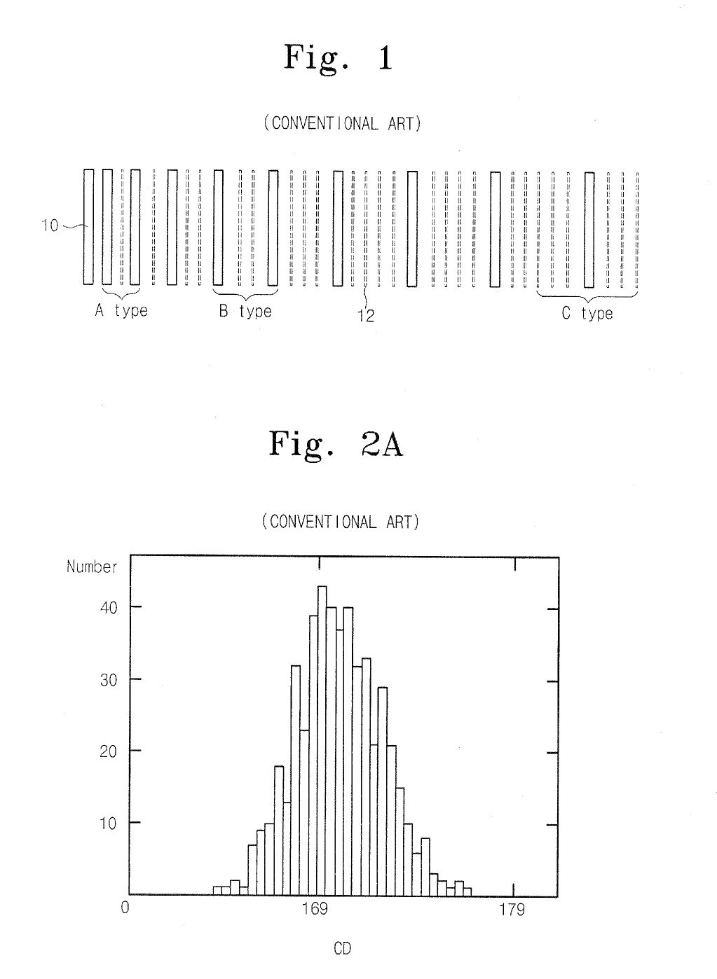

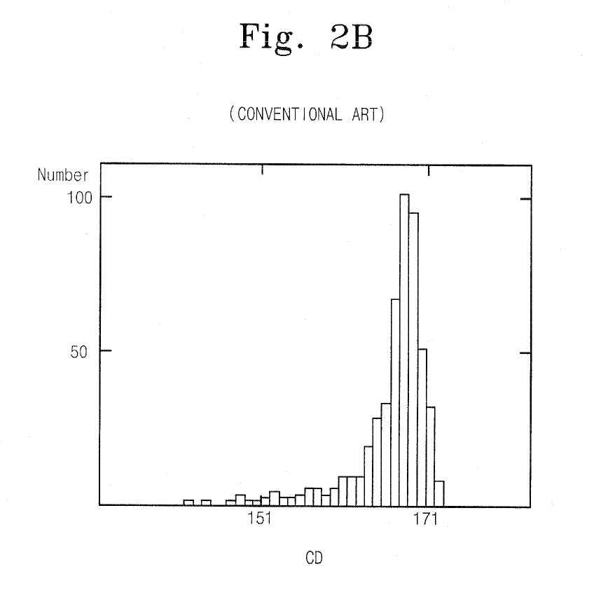

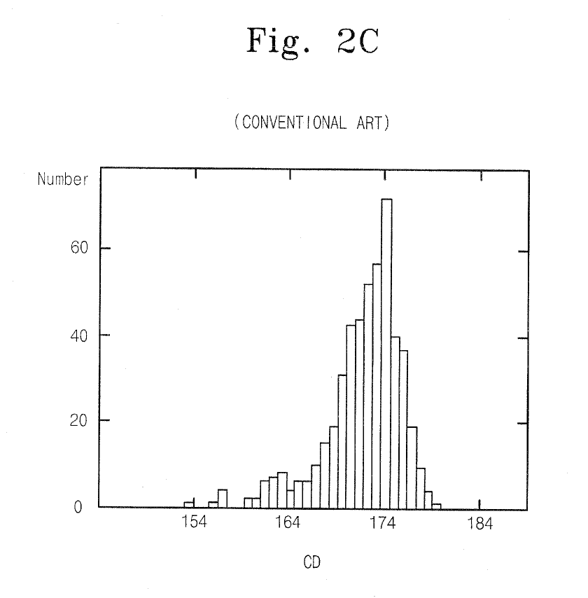

### DETAILED DESCRIPTION

The invention will now be described hereinafter with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the widths of patterns and regions are exaggerated for clarity. Like reference numerals refer to like elements throughout the drawings.

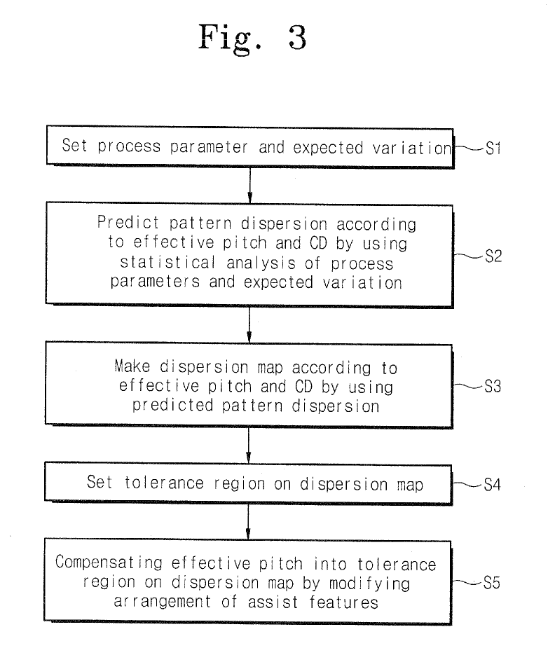

FIG. 3 is a flowchart illustrating a pattern arrangement method according to an embodiment of the invention.

Referring to FIG. 3, in operation S1, process parameters influencing the dispersion of patterns transferred on a wafer, and variations of the process parameters are set. The operation S1 is a prerequisite process and the process parameters can be obtained empirically and experimentally. As illustrated in Table 1 below, the process parameters influencing the dispersion of the patterns may be selected to include parameters from the exposure process, the optical system, the photoresist, and the development process.

TABLE 1

| CLASS. | FACTOR |
|---|---|
| Exposure energy | illumination uniformity, flare, thickness of photoresist, |
| | bake energy, transmittance |
| Focus | focus adjustment, polarization, flatness of reticle, |
| | flatness of chuck, topology of wafer |
| Mask pattern | CD uniformity, slope |
| Others | aberration, phase, development loading effect |

In addition to the factors illustrated in Table 1, additional process parameters influencing the dispersion of the patterns may arise during the actual semiconductor manufacturing process. These process parameters may be added during the prerequisite process. Expected variations of the process parameters can be set based on the tolerance of the exposure system and facilities and the tolerance of the process control governing the lithography process.

In operation S2, pattern dispersion based on effective pitches and CDs is predicted using a statistical analysis of the set process parameters and the expected variations thereof. Like the related art samples used for the dispersion prediction, the pattern dispersion can be classified according to CDs and pitches. Basically, the samples may be sub-resolution assist features and/or resolution assist features that are arranged according to the conventional design rule having a strong structural dependence. The effective pitch is the pitch of a bar pattern which is seen by exposure light in response to the arrangement of the assist features, and it can be calculated using a general design tool. In the dispersion prediction, a probability distribution of the CD is established by randomly selecting the process parameters using Monte Carlo simulation and the pattern dispersion corresponding to the pitch and CD of the patterns can be predicted from the established probability distribution.

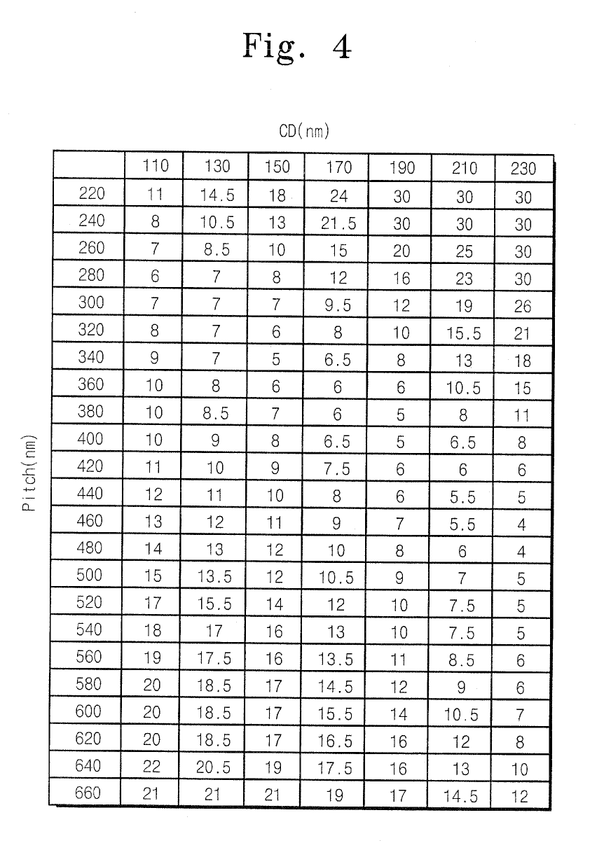

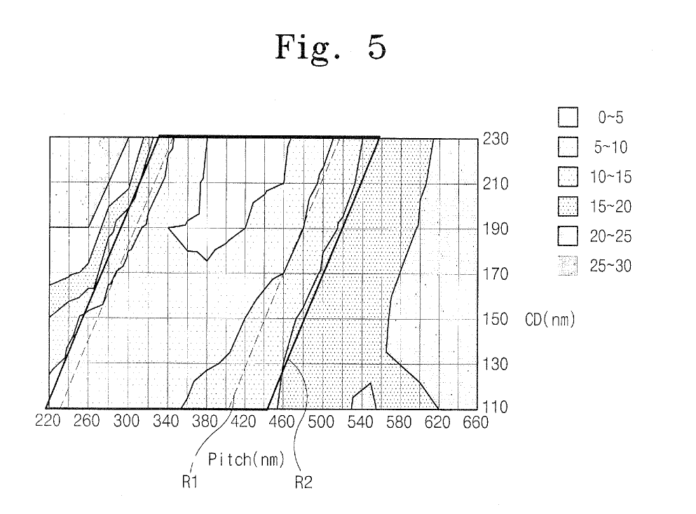

FIG. 4 is a table listing the dispersion (3σ) of the pattern CDs transferred on the wafer according to the effective pitches and the CDs. Specifically, FIG. 4 shows the dispersion of the CDs divided into predetermined ranges. In operation S3, a dispersion map according to the effective pitches and the CDs of the patterns is made by dividing the dispersion into the predetermined regions in the table of FIG. 4.

As illustrated in FIG. 5, the dispersion map according to the effective pitches and the CDs of the patterns can be made by standardizing the dispersion in the predetermined regions. The dispersion map can be made more accurately by subdividing the effective pitches and the CDs. In the dispersion map, the regions have dispersion ranges of 0-5 nm, 5-10 nm, 10-15 nm, 20-25 nm, and 25-30 nm.

The significance of a mask layer is different depending on the operation and design requirements of the semiconductor device. Even the same layer may have a region requiring a strict process control and a region having a large process tolerance. By reflecting these design factors, the tolerance of the pattern dispersion is determined. In the semiconductor device, the dispersion tolerance is strictly controlled in a layer for forming a pattern such as the gate pattern that influences circuit operation. In the layer for forming the gate pattern, a gate pattern on an active region may be controlled more strictly than a gate pattern on a field region. Therefore, in operation S4, the tolerance region satisfying the predefined dispersion tolerance is determined in the dispersion map. For example, as illustrated in FIG. 5, a tolerance region R1 having dispersion of below 10 nm and a tolerance region R2 having dispersion of 10-20 nm can be determined. The gate patterns may be arranged in such a way that the gate pattern on the active region is controlled in the tolerance region R1 and the gate pattern on the field region is controlled in the tolerance region R2. In other words, the gate pattern on an active region, requiring strict dispersion control, may be controlled in the tolerance region RI having dispersion of below 10 nm, while the gate pattern on a field region, requiring less strict dispersion control, may be controlled in the tolerance region R2, having dispersion of 10-20 nm. Controlling the dispersion within these dispersion tolerances may improve the reliability of the semiconductor device.

In the semiconductor device, patterns having various pitches and CDs may be arranged in the same mask layer. The pitches and the CDs of the patterns may be changeable or unchangeable according to design requirements and available space. In operation S5, when coordinates corresponding to effective pitches and CDs of patterns to be formed in the mask layer are out of the tolerance region, the effective pitches are compensated, thereby moving the coordinates within the tolerance region in the dispersion map.

For example, bar patterns having the CD of 170 nm are arranged at intervals of 500 nm, 650 nm, and 800 nm on an actual mask, and samples where the assist features that can obtain the effective pitch of 75% are arranged between the bar patterns, according to the conventional design rule, have the effective pitches of 375 nm, 488 nM, and 600 nm.

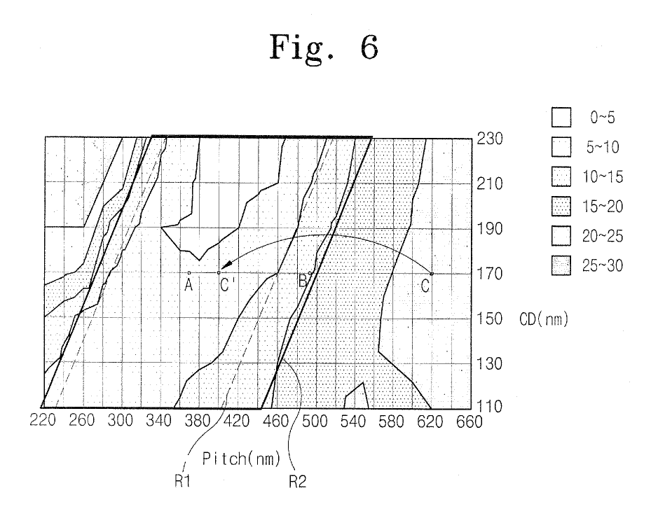

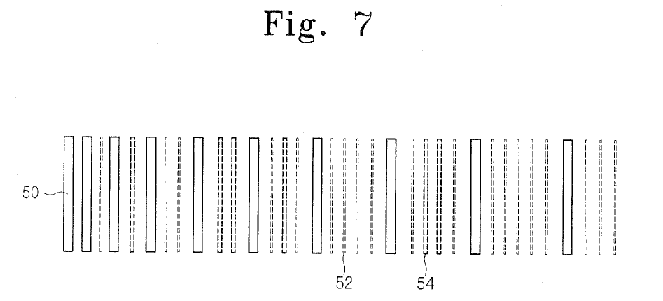

As illustrated in FIG. 6, the coordinates of the samples corresponding to the effective pitches and CDs are located at coordinates A, coordinates B, and coordinates C in the dispersion map. The coordinates A of the sample having the effective pitch of 375 nm are included within the tolerance region having the dispersion of below 10 nm and the coordinates B of the sample having the effective pitch of 488 nm are included within the tolerance region having the dispersion of 10-15 nm. Accordingly, coordinates A are located within region R1 and coordinates B are located within region R2. On the other hand, the coordinates C of the sample having the effective pitch of 600 nm are included within the tolerance region having the dispersion of 20-25 nm. Accordingly, coordinates C are located outside of both regions R1 and R2. Therefore, when the dispersion tolerance of the patterns having the CD of 170 nm and arranged in the mask layer is set to 20 nm, the patterns having the effective pitch corresponding to the coordinates C are out of the tolerance region. In other words, if the dispersion tolerance is set to 20 nm, coordinates C need to fall within a region of the dispersion map that has dispersion less than 20 nm, for example region R2, to be acceptable. Since coordinates C fall in a region of the dispersion map that has dispersion of 25-30 nm, using the lithography process to create patterns having the parameters of coordinates C will not yield patterns that are within the acceptable range. According to the invention, the pitches of the patterns arranged in the mask layer are compensated by modifying the arrangement of the patterns, thereby moving the coordinates C into the tolerance region, such as the coordinates C′. Alternatively, the effective pitch is compensated by determining a region for an assist feature arrangement and arranging assist features in the determined region in a space between the patterns. That is, when the assist feature is arranged according to the conventional design rule and the effective pitch is calculated, the effective pitch of the pattern having the effective pitch corresponding to the coordinates C is changed into the coordinates C′ by modifying the number, CD, and pitch of the assist feature. For example, the effective pitch can be compensated into 400 nm by modifying a 75% sub-resolution assist feature into a resolution assist feature between the patterns having the pitch of 800 nm. This modification of the assist feature results in the coordinates C′ which is within the dispersion tolerance of 20 nm.

When the effective pitch is compensated, sub-resolution assist features which are not transferred on the wafer and resolution assist features which are transferred on the wafer but do not influence the operation of the device can be appropriately combined and arranged. In this case, the effective pitch in the arrangement of the sub-resolution assist feature and the resolution assist feature can be calculated in the design tool. In addition, sequences may be programmed to select a combination, a calculated effective pitch of which is close to a minimum dispersion of the tolerance region among the possible combinations. In other words, several possible arrangements of assist features, both sub-resolution and resolution, can be calculated and checked against the dispersion map. Once the arrangements have been checked, an optimum arrangement may be selected. The optimum arrangement should result in coordinates C′ that are within the tolerance region. The optimum arrangement may also be selected such that it results in coordinates having a minimum possible dispersion.

FIG. 7 illustrates an arrangement of assist features corresponding to pattern pitches according to an embodiment of the invention.

According to the related art, the assist patterns are arranged depending on only the pitches and CDs of the patterns and the assist features are formed between the patterns based on these parameters. However, according to the invention, as illustrated in FIG. 7, the combination of the assist features that can approach the minimum dispersion among the dispersions according to the process parameters can be selected. Thus, the sub-resolution assist feature 52 and the resolution assist feature 54 can be appropriately arranged between the main patterns 50 to provide minimum dispersion of the main patterns 50. In this way, the pattern produced on a wafer can more closely approximate the desired semiconductor device pattern.

As described above, because the dispersion map according to the effective pitches and the CDs is made, and the design patterns are arranged to lie within the tolerance regions, the patterns can be arranged such that they can satisfy the dispersion tolerance according to the significance of the layer and the design requirements. In the dispersion map according to the invention, the dispersion can be predicted from the probability distribution of the variable CDs through statistical analysis by including the process parameters causing the change of the CDs. Therefore, the invention can solve the problems of the design rule that is dependent on the CDs and pitches of the patterns arranged in the mask layer, the slopes of the patterns, and the like. Consequently, the pattern arrangement satisfying the dispersion tolerance in which the changes due to process parameters is considered can be designed.

Embodiments of the invention provide pattern arrangement methods using a pattern dispersion predicted according to process parameters. In the pattern arrangement method, patterns are classified according to effective pitches and critical dimensions, and pattern dispersion is predicted according to the effective pitches and the critical dimensions by using a statistical analysis of process parameters. Two-dimensional coordinates of the effective pitches and the critical dimensions are constructed, and a dispersion map is made by arranging the predicted pattern dispersion on the corresponding coordinates.

A tolerance region satisfying a dispersion tolerance is determined in the dispersion map. At this point, the tolerance region can be determined by a designer, considering the significance of the mask layer and a location relationship with other layers during a semiconductor manufacturing process. The effective pitch of the patterns outside of the tolerance region is compensated to move the patterns into the tolerance region. The effective pitch of the patterns outside of the tolerance region can be compensated into the tolerance region by modifying the arrangement of the assist features and the patterns themselves.

Consequently, it is possible to manufacture the mask layer that has the dispersion tolerance required in the design by compensating the arrangement of the patterns outside of the dispersion region exceeding the tolerance, taking into account the process parameters.

The above-disclosed subject matter is to be considered illustrative, and not restrictive, and the appended claims are intended to cover all such modifications, enhancements, and other embodiments, which fall within the true spirit and scope of the invention. Thus, to the maximum extent allowed by law, the scope of the invention is to be determined by the broadest permissible interpretation of the following claims and their equivalents, and shall not be restricted or limited by the foregoing detailed description.

What is claimed is:

1. A pattern arrangement method comprising:
classifying patterns according to effective pitches and critical dimensions;
predicting pattern dispersion according to the effective pitches and the critical dimensions by using a statistical analysis of process parameters;
constructing two-dimensional coordinates of the effective pitches and the critical dimensions;
creating a dispersion map by arranging the predicted pattern dispersion on the corresponding coordinates;
determining a tolerance region satisfying a dispersion tolerance in the dispersion map; and
compensating the effective pitches of patterns of which coordinates of the effective pitches and the critical dimensions are outside of the tolerance region in the dispersion map, thereby moving the coordinates within the tolerance region.

2. The pattern arrangement method of claim 1, wherein the predicting of the pattern dispersion comprises analyzing the dispersion using Monte Carlo simulation including at least one process parameter.

3. The method of claim 2, wherein the analyzing of the dispersion comprises:
preparing samples classified by critical dimensions and effective pitches;
randomly selecting process parameters as a dispersion variation factor;
establishing a probability distribution from each of the samples by applying the selected process parameters to the samples; and
calculating the dispersion in the established probability distribution.

4. The method of claim 3, wherein the dispersion is a critical dimension dispersion for the process parameters.

5. The method of claim 1, wherein the predicting of the pattern dispersion comprises:
arranging assist features between main patterns by applying a structural-dependent design rule; and
calculating the effective pitches.

6. The method of claim 5, wherein the effective pitches are compensated by modifying at least one of the number, critical dimension, and pitch of the assist features.

7. The method of claim 5, wherein the assist features comprise sub-resolution assist features and resolution assist features, and the effective pitches are compensated by modifying the number, critical dimension, and pitch of the sub-resolution assist features and the resolution assist features.

8. The method of claim 7, wherein the compensating of the effective pitches comprises:
determining an arrangement region of the assist features;
calculating the effective pitches by modifying the number, critical dimension, and pitch of the sub-resolution assist features and the resolution assist features; and
selecting a combination of the assist features having the effective pitch closest to a minimum dispersion in a tolerance range of the dispersion map.

9. The method of claim 1, wherein the effective pitch is compensated by adding assist features.

10. The method of claim 9, wherein the assist features comprise sub-resolution assist features and resolution assist features, and the effective pitch is compensated by modifying the number, critical dimension, and pitch of the sub-resolution assist features and the resolution assist features.

11. The method of claim 10, wherein the compensating of the effective pitch comprises:
determining an arrangement region of the assist feature;
calculating the effective pitch by modifying the number, critical dimension, and pitch of the sub-resolution assist features and the resolution assist features; and
selecting a combination of the assist features having the effective pitch closest to a minimum dispersion in a tolerance range of the dispersion map.

12. The method of claim 10, wherein the dispersion is a critical dimension dispersion that changes according to the effective pitches and the critical dimensions of the patterns.

13. The method of claim 1, wherein a tolerance range of the dispersion is determined by a significance of the patterns.

14. A pattern arrangement method, comprising:
predicting a pattern dispersion for a pattern, wherein predicting the pattern dispersion comprises analysis of process parameters;
generating a dispersion map using the predicted pattern dispersion;
determining a dispersion tolerance;
identifying a tolerance region in the dispersion map according to the dispersion tolerance; and
determining a coordinate point on the dispersion map for the pattern using an effective pitch and a critical dimension of the pattern;
altering the pattern if the coordinate point is outside of the tolerance region in the dispersion map.

15. The method of claim 14, wherein altering the pattern moves the coordinate point within the tolerance region of the dispersion map.

16. The method of claim 14, wherein altering the pattern comprises modifying assist features.

17. The method of claim 16, wherein modifying the assist features comprises changing at least one of the number, critical dimension, and pitch of the assist features.

18. The method of claim 17, wherein the assist features comprise sub-resolution assist features and resolution assist features.

19. The method of claim 16, wherein altering the pattern comprises:
calculating a modified coordinate point for each of a plurality of assist feature arrangements;
evaluating each modified coordinate point using the dispersion map;
selecting the assist feature arrangement corresponding to the modified coordinate point that has a minimum dispersion in the tolerance region on the dispersion map.

20. The method of claim 14, wherein identifying a tolerance region comprises determining a significance of the pattern.
